(19) United States
(12) Patent Application Publication
(10) Pub. No.: US 2008/0116543 A1
(43) Pub. Date: May 22, 2008

(54) Semiconductor devices and methods of manufacture thereof

(76) Inventor: Shrinivas Govindarajan, Austin, TX (US)

Correspondence Address: SLATER & MATSIL LLP, 17950 PRESTON ROAD, SUITE 1000, DALLAS, TX, 75252, US

(21) Appl. No.: 11/601,166

(22) Filed: Nov. 17, 2006

(51) Int. Cl. H01L 21/469; H01L 23/58

(52) U.S. Cl. 257/639; 438/785; 257/E21.487; 257/E23.002

(57) ABSTRACT

Semiconductor devices and methods of manufacture thereof are disclosed. A preferred embodiment comprises a method of forming a material layer. The method includes forming at least one first layer of a first material, and forming at least one second layer of a second material over the at least one first layer of the first material. The first material comprises an oxide or a silicate of Hf, Zr, or La. The second material comprises a silicon oxynitride of Hf, Zr, or La.

### TECHNICAL FIELD

The present invention relates generally to the fabrication of semiconductors, and more particularly to high dielectric constant insulating materials and methods of formation thereof.

### BACKGROUND

Generally, semiconductor devices are used in a variety of electronic applications, such as computers, cellular phones, personal computing devices, and many other applications. Home, industrial, and automotive devices that in the past comprised only mechanical components now have electronic parts that require semiconductor devices, for example.

Semiconductor devices are manufactured by depositing many different types of material layers over a semiconductor workpiece or wafer, and patterning the various material layers using lithography. The material layers typically comprise thin films of conductive, semiconductive, and insulating materials that are patterned and etched to form integrated circuits (IC's). There may be a plurality of transistors, memory devices, switches, conductive lines, diodes, capacitors, logic circuits, and other electronic components formed on a single die or chip.

Insulating materials comprise dielectric materials that are used in many types of semiconductor devices. Silicon dioxide (SiO₂) is a common dielectric material used in semiconductor device manufacturing, for example, which has a dielectric constant or k value of about 3.9. Some semiconductor applications require the use of a high k dielectric material having a higher k value than the k value of silicon dioxide, for example. Some transistors require a high k dielectric material as a gate dielectric material, and some capacitors require a high k dielectric material as an insulating material between two conductive plates, as examples, to reduce leakage current and reduce capacitance.

A dynamic random access memory (DRAM) is a memory device that can be used to store information. A DRAM cell in a memory array typically includes two elements, namely a storage capacitor and an access transistor. Data can be stored into and read out of the storage capacitor by passing a charge through the access transistor and into the capacitor. The capacitance, or amount of charge held by the capacitor per applied voltage, is measured in farads and depends upon the area of the plates, the distance between them, and the dielectric value of the insulator, as examples.

High k dielectric materials are typically used as an insulating material in the storage capacitor of DRAM cells. Examples of some high dielectric constant materials that have been proposed as capacitor dielectrics are hafnium oxide and hafnium silicate. However, these materials are limited to a maximum dielectric constant of around 30, for example.

What are needed in the art are improved high dielectric constant (k) dielectric materials and methods of formation thereof in semiconductor devices.

### SUMMARY OF THE INVENTION

These and other problems are generally solved or circumvented, and technical advantages are generally achieved, by preferred embodiments of the present invention, which provide improved methods of forming high k dielectric materials and structures thereof.

In accordance with a preferred embodiment of the present invention, a method of forming a material layer includes forming at least one first layer of a first material, the first material comprising an oxide or a silicate of Hf, Zr, or La. At least one second layer of a second material is formed over the at least one first layer of the first material, the second material comprising a silicon oxynitride of Hf, Zr, or La.

The foregoing has outlined rather broadly the features and technical advantages of embodiments of the present invention in order that the detailed description of the invention that follows may be better understood. Additional features and advantages of embodiments of the invention will be described hereinafter, which form the subject of the claims of the invention. It should be appreciated by those skilled in the art that the conception and specific embodiments disclosed may be readily utilized as a basis for modifying or designing other structures or processes for carrying out the same purposes of the present invention. It should also be realized by those skilled in the art that such equivalent constructions do not depart from the spirit and scope of the invention as set forth in the appended claims.

### BRIEF DESCRIPTION OF THE DRAWINGS

For a more complete understanding of the present invention, and the advantages thereof, reference is now made to the following descriptions taken in conjunction with the accompanying drawings, in which:

FIG. 1 is a flow chart illustrating a method of forming a high k dielectric material in accordance with a preferred embodiment of the present invention, wherein the high k dielectric material comprises a nanolaminate material including a plurality of alternating layers of a first material and a second material;

FIGS. 2 and 3 show cross-sectional views of a semiconductor device in accordance with an embodiment of the present invention at various stages of manufacturing;

FIG. 4 shows a more detailed view of the nanolaminate material shown in FIG. 3;

FIGS. 5 and 6 show cross-sectional views of a semiconductor device in accordance with an embodiment of the present invention at various stages of manufacturing;

FIGS. 7 and 8 show cross-sectional views of a semiconductor device at various stages of manufacturing, wherein the novel high k dielectric material of embodiments of the present invention is implemented in a metal-insulator-metal (MIM) capacitor structure;

FIG. 9 shows a cross-sectional view of a semiconductor device, wherein the novel high k dielectric material of embodiments of the present invention is implemented in a transistor structure; and

FIGS. 10 and 11 show cross-sectional views of a semiconductor device at various stages of manufacturing, wherein the novel high k dielectric material of embodiments of the present invention is implemented in a DRAM structure.

Corresponding numerals and symbols in the different figures generally refer to corresponding parts unless otherwise indicated. The figures are drawn to clearly illustrate the relevant aspects of the preferred embodiments and are not necessarily drawn to scale.

### DETAILED DESCRIPTION OF ILLUSTRATIVE EMBODIMENTS

The making and using of the presently preferred embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

The present invention will be described with respect to preferred embodiments in a specific context, namely the formation of high k dielectric materials in semiconductor devices such as capacitors and transistors. The invention may also be applied, however, to the formation of dielectric materials in other applications where a high k dielectric material is required, for example.

Embodiments of the present invention achieve technical advantages by providing novel processing solutions for the formation of high k dielectric materials. The novel dielectric materials to be described herein have a high k value, a low leakage current, good uniformity, and high temperature thermal stability. The dielectric materials are formed using a nanolaminate structure, which may be used to optimize silicon and nitrogen content in the film and to stabilize a high k phase of HfO₂ or ZrO₂ in the nanolaminate structure, to be described further herein.

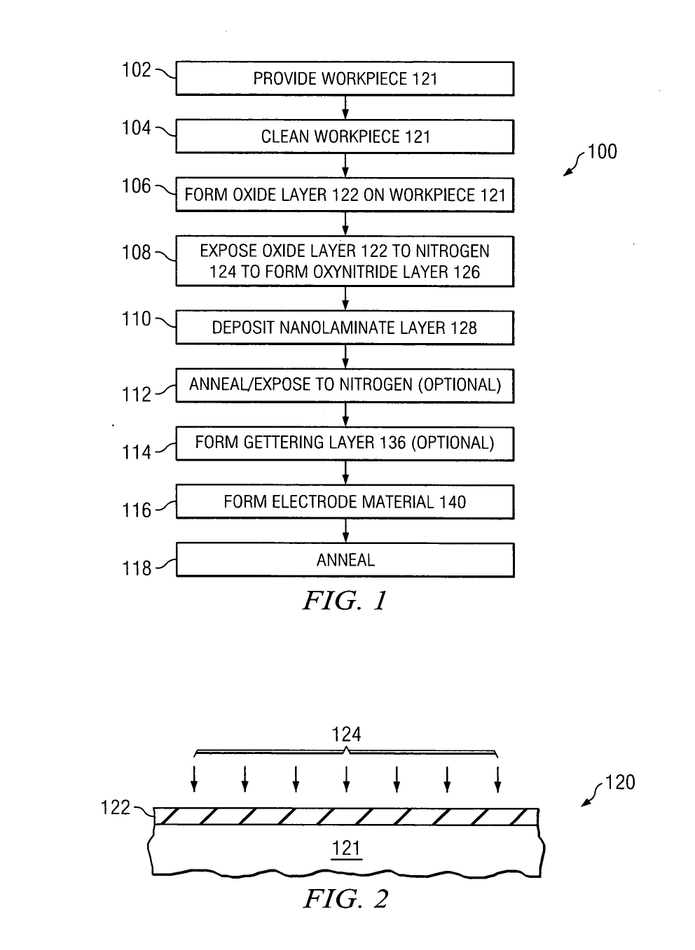

FIG. 1 is a flow chart 100 illustrating a method of forming a high k dielectric material 128 in a semiconductor device 120 (see FIG. 2) in accordance with a preferred embodiment of the present invention, wherein the high k dielectric material 128 comprises a nanolaminate stack including a plurality of alternating layers of a first material 130 and a second material 130. FIGS. 2, 3, 5, and 6 show cross-sectional views of a semiconductor device 120 in accordance with an embodiment of the present invention at various stages of manufacturing, wherein the nanolaminate stack is formed on a planar semiconductor device 120.

Referring to the flow chart 100 in FIG. 1 and also to the semiconductor device 120 shown in FIG. 2, first, a workpiece 121 is provided (step 102). The workpiece 121 may include a semiconductor substrate comprising silicon or other semiconductor materials covered by an insulating layer, for example. The workpiece 121 may also include other active components or circuits, not shown. The workpiece 121 may comprise silicon oxide over single-crystal silicon, for example. The workpiece 121 may include other conductive layers or other semiconductor elements, e.g., transistors, diodes, etc. Compound semiconductors, GaAs, InP, Si/Ge, or SiC, as examples, may be used in place of silicon. The workpiece 121 may comprise a silicon-on-insulator (SOI) substrate, for example.

The workpiece 121 is cleaned (step 104). For example, the workpiece 121 may be cleaned to remove debris or contaminants. In a preferred embodiment, the workpiece 121 is cleaned with ozone (O₃), for example, which may result in the formation of a chemical oxide layer. The cleaning step 104 preferably results in a good interface for the subsequent deposition of thin dielectric material layers thereon, for example.

Preferably, the cleaning step 104 results in the formation of an oxide layer 122 comprising an oxide material such as silicon dioxide (SiO₂) over the workpiece 121, as shown in FIG. 2. Alternatively, the oxide layer 122 may be formed using an optional additional oxidation or deposition step (step 106), and the oxide layer 122 may also comprise other materials, for example. The oxide layer 122 preferably comprises a thickness of about 10 Angstroms or less, for example, although alternatively, the oxide layer 122 may comprise other dimensions.

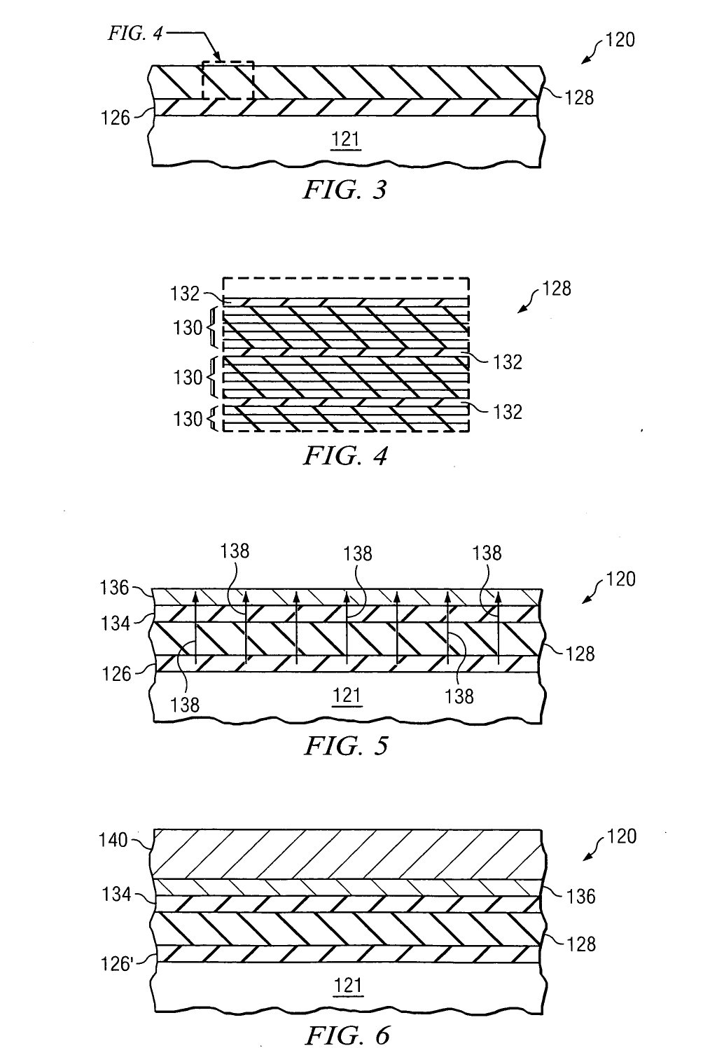

The workpiece 121, e.g., the oxide layer 122 formed on the top surface of the workpiece 121, is exposed to nitrogen 124 to form an oxynitride layer 126 from the oxide layer 122, as shown in FIGS. 2 and 3 (step 108 of FIG. 1). The oxynitride layer 126 preferably comprises a silicon oxynitride (SiOₓN_{y}) layer 126 that is formed from an oxide layer 122 comprising SiO₂, for example, although alternatively, the oxynitride layer 126 may comprise other materials.

Next, a nanolaminate layer 128 is formed over the oxynitride layer 126, as shown in FIG. 3 (step 110). The nanolaminate layer 128 is also referred to herein as a nanolaminate material, a dielectric material, and a nanolaminate stack, for example. FIG. 4 shows a more detailed view of the nanolaminate layer 128 shown in FIG. 3. The nanolaminate layer 128 is preferably formed by forming at least one first layer 130 over the oxynitride layer 126 and forming at least one second layer 132 over the at least one first layer 130. The first layer 130 preferably comprises a first material, and the second layer 132 comprises a second material, wherein the second material is different than the first material.

The first material of the first layer 130 preferably comprises an oxide or silicate of hafnium (Hf), zirconium (Zr), or lanthanum (La). For example, the first material of the first layer 130 preferably comprises hafnium oxide (HfO₂), zirconium oxide (ZrO₂), hafnium silicate (HfSiO), or zirconium silicate (ZrSiO). The second material of the second layer 132 preferably comprises a silicon oxynitride of Hf, Zr, or La. For example, the second material of the second layer 132 preferably comprises hafnium silicon oxynitride (HfSiON) or zirconium silicon oxynitride (ZrSiON). The first material of the first layer 130 and the second material of the second layer 132 may alternatively comprise other materials, for example.

The at least one first layer 130 and the at least one second layer 132 form a dielectric material 128. In some embodiments, for example, the nanolaminate layer 128 comprises a dielectric material comprised of a plurality of alternating layers of the at least one first layer 130 of the first material and the at least one second layer 132 of the second material.

For example, in the more detailed view of FIG. 4, an embodiment is shown wherein the nanolaminate layer 128 comprises several, e.g., five layers of the first layer 130 and one layer of the second layer 132. Additional alternating layers of five layers of the first layer 130 and one layer of the second layer 132 may be successively formed over the previously formed layers 130/132. Alternatively, different numbers of the first layer 130 and the second layer 132 may also be used, for example.

The nanolaminate layer 128 preferably comprises a first number of the first layers 130 of the first material and a second number of the second layers 132 of the second material. The first number and the second number may be varied to adjust the overall composition of the nanolaminate layer 128, e.g., to adjust properties of the nanolaminate layer 128. For example, the first number and the second number of the first layers 130 and the second layers 132, respectively, may be varied to adjust a dielectric constant of the dielectric material, e.g., of the nanolaminate layer 128. The second number may be the same as the first number, or the second number may be different than the first number, for example. The first number may range from about 1 to 50, and the second number may range from about 1 to 50, as examples, although other numbers of layers 130 and 132 may also be used depending on the desired properties of the nanolaminate layer 128.

The first layers 130 of the first material are preferably deposited by atomic layer deposition (ALD), for example, although alternatively, other deposition processes may also be used. The first layer 130 of the first material may comprise a monolayer or several monolayers of the first material, for example. Likewise, the second layers 132 of the second material are preferably deposited by ALD, for example, although alternatively, other deposition processes may also be used. The second layer 130 of the second material may comprise a monolayer or several monolayers of the second material, for example. The thickness of the individual layers, e.g., the thickness of each first layer 130 and second layer 132, may be modified by varying the number of cycles of ALD deposition, for example.

Each first layer 130 and each second layer 132 preferably comprises a thickness of about 10 Angstroms or less, and more preferably comprises a thickness of about 2 to 8 Angstroms, although alternatively, the first layers 130 and second layers 132 may comprise other dimensions. ALD is preferably used for the formation of the first layers 130 and second layers 132 because this deposition technique is well-controlled and produces very thin material layers with continuous coverage.

The nanolaminate layer 128 may comprise various combinations of the preferred materials mentioned above for the first layer 130 and the second layer 132. For example, the nanolaminate layer 128 preferably comprises a HfO₂—HfSiON nanolaminate material, a HfSiO—HfSiON nanolaminate material, a ZrO₂—ZrSiON nanolaminate material, a ZrSiO—ZrSiON nanolaminate material, a HfO₂—ZrSiON nanolaminate material, a ZrO₂—HfSiON nanolaminate material, a ZrSiO—HfSiON nanolaminate material, or a HfSiO—ZrSiON nanolaminate material, as examples, although other combinations of material layers may also be used. The nanolaminate layer 128 may also comprise alternating layers of La-containing material layers or combinations thereof with Hf-containing and/or Zr-containing material layers, for example.

In some embodiments, the first layer 130 preferably comprises a non-nitride material, and the second layer 132 preferably comprises a nitride material, for example. The non-nitride material of the first layer 130 provides a good interface to the workpiece 121, e.g., to the oxynitride layer 122 disposed over the workpiece 121, for example, and the nitride material of the second layer 132 provides a higher dielectric constant material than the first layer 130, thus increasing the overall k value of the nanolaminate layer 128, for example.

In some embodiments, because the second layer 132 comprises a silicon oxynitride of Hf, Zr, or La which may result in a thickness non-uniformity if a large number of monolayers are deposited, due to a difficulty in nucleation of the film, preferably the number of layers of the second layer 132 is fewer than the number of layers of the first layer 130. For example, one to three layers of the second layer 132 are preferably deposited adjacent to one another in the nanolaminate layer 128, whereas four or more layers of the first layer 130 not comprising a nitride may be deposited adjacent to one another in the nanolaminate layer 128 material stack. Thus, the second layers 132 within the stack maintain a more uniform thickness.

The nanolaminate layer 128 advantageously comprises a dielectric material stack that has a high k value, for example. In the embodiments wherein the first layer 130 comprises an oxide of Hf or Zr, which have a tendency to form a monoclinic phase of these materials, a dielectric constant between 18 and 21 is achieved. In the embodiments wherein the first layers 130 comprise a silicate of Hf or Zr, a tetragonal phase of these materials is formed, resulting in an even higher dielectric constant, e.g., about 30 for HfSiO and about 40 for ZrSiO. The nitrogen in the second material 132 advantageously lowers leakage current, e.g., even after high thermal budget operations.

The nanolaminate layer 128 is then subjected to a post deposition anneal (step 112). During the anneal process, nitrogen may optionally be introduced (step 112), to form a nitrided layer 134 at a top surface of the nanolaminate layer 128, as shown in FIG. 5. The anneal process preferably comprises annealing the workpiece 121 at a temperature of between about 500 and 850 degrees C., for about 10 to 120 seconds, at a pressure of between about 15 to 100 Torr, e.g., in an NH₃ ambient, although other processing conditions may also be used for the anneal process (e.g. N₂). The nitrided layer 134 preferably comprises a layer of either Hf or Zr silicon oxynitride with an increased amount of nitrogen, having a thickness of about 20 Angstroms or less, for example.

Next, an optional gettering layer 136 is formed over the optional nitrided layer 134 (step 114), as shown in FIG. 5, or over the nanolaminate layer 128, if the nitrided layer 134 is not formed. The gettering layer 136 preferably comprises a material such as titanium (Ti) that is adapted to cause oxygen 138 to move upwardly from the oxynitride layer 126 through the nanolaminate layer 128, for example. The gettering layer 136 preferably comprises a thickness of about 0.5 nm to about 2 nm or less, for example, although the gettering layer 136 may also comprise other dimensions. The oxygen 138 (O) moves up through the nanolaminate stack 128, forming TiO₂ at the interface of the Ti gettering layer 136. In the gettering process, at least a portion, and in some embodiments, substantially all, of the oxygen from the oxynitride 126 layer is removed, forming a layer 126′ comprising silicon nitride SiₓN_{y}, for example, as shown in FIG. 6. The layer 126′ after the gettering layer 136 is deposited may comprise a nitride layer, for example.

Note that the oxynitride layer 126 initially adds to the effective oxide thickness (EOT) of the dielectric stack (e.g., materials 126, 128, and 134). However, the oxynitride layer 126 advantageously provides a good quality starting oxide layer for the deposition process of the nanolaminate layer 128. Later, if the gettering layer 136 is included, the gettering layer 136 is used to minimize the EOT by reducing the thickness of the oxynitride layer 126, by removing all or some of the oxygen from the oxynitride layer 126, for example.

An electrode material 140 is formed over the optional gettering layer 136 (step 116), as shown in FIG. 6. The electrode material 140 preferably comprises a conductive material such as TiN, TaN, RuO₂, TiSiN, or multiple layers or combinations thereof, as examples, although other materials such as a semiconductor material, e.g., polysilicon may also be used. The electrode material 140 preferably comprises a thickness of about 15 nm or less, for example, although the electrode material 140 may also comprise other dimensions. The electrode material 140 is preferably deposited using ALD, although other deposition methods such as chemical vapor deposition (CVD) or physical vapor deposition (PVD) may also be used.

Note that in some embodiments, the electrode material 140 is preferably deposited in-situ with the gettering layer 136. For example, the workpiece 121 may be placed in a processing chamber, and without removing the workpiece 121 from the processing chamber, first the gettering layer 136 is formed, and then the electrode material 140 is formed over the gettering layer 136.

Next, the semiconductor device 120 is annealed (step 118). The anneal process is a key process step, preferably comprising a high temperature activation anneal. The anneal process preferably is carried out at temperatures greater than or equal to 1,000° C., for a duration of greater than about 10 seconds, in a nitrogen ambient with up to about 8% oxygen, as an example, although alternatively, the final anneal process may comprise other processing parameters.

The various material layers 140, 136, 134, 128 and 126′ are then patterned into desired shapes for the semiconductor device 120, not shown. For example, the material layers 140 and 136 that are conductive may be patterned in the shape of a capacitor plate, a transistor gate, or other conductive elements or portions of circuit elements, as examples. The material layers 134, 128 and 126′ that are insulators may also be patterned, for example, also not shown.

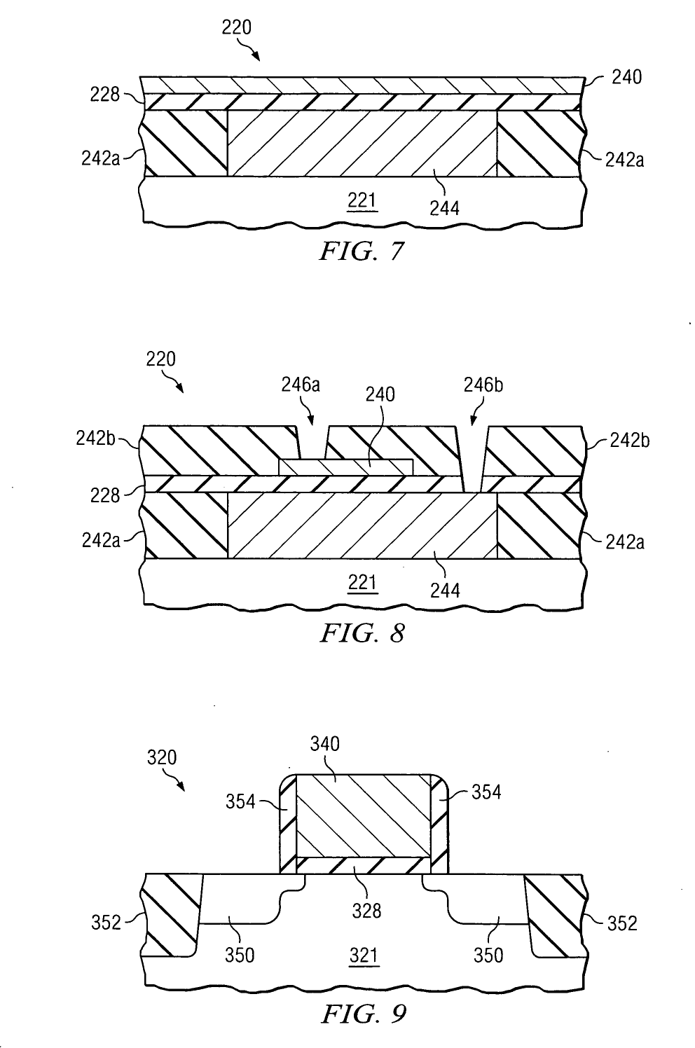

FIGS. 7 and 8 show cross-sectional views of a semiconductor device 220 at various stages of manufacturing, wherein the novel high k dielectric material 228 of embodiments of the present invention is implemented in a metal-insulator-metal (MIM) capacitor structure, for example. Like numerals are used for the various elements that were described in FIGS. 2 through 6. To avoid repetition, each reference number shown in FIG. 7 and 8 is not described again in detail herein. Rather, similar materials x21, x22, x26, x28, etc . . . are preferably used for the various material layers shown as were described for FIGS. 2 through 6, where x=1 in FIGS. 2 through 6 and x=2 in FIGS. 7 and 8.

To form the MIM capacitor, a bottom capacitor plate 244 is formed over a workpiece 221. The bottom plate may comprise a semiconductive material such as polysilicon, or a conductive material such as copper or aluminum, as examples. The bottom capacitor plate 244 may be formed in an insulating material 242a that may comprise an inter-level dielectric layer (ILD), for example. The bottom capacitor plate 244 may include liners and barrier layers, for example, not shown.

The novel high k dielectric material 228 described with reference to FIGS. 1 through 6 is formed over the bottom plate 244 and the insulating material 242a. A nitride layer 126′, a nitrided layer 134, and gettering layer 136 as shown in FIG. 6 may also be included in the structure, for example (not shown in FIG. 7). An electrode material 240 is formed over the dielectric material 228, as shown in FIG. 7, and the electrode material 240 (and also the gettering layer 136 if included, not shown) is patterned to form a top capacitor plate, as shown in FIG. 8. An additional insulating material 242b may be deposited over the top capacitor plate 240, and the insulating material 242b (and also the nanolaminate layer 228) may be patterned with patterns 246a and 246b for contacts that will make electrical contact to the top plate 240 and the underlying bottom plate 244, respectively. The insulating material 242b may be filled in later with a conductive material to form the contacts, for example, not shown.

Thus, in FIG. 8, a capacitor is formed that includes the two conductive plates 244 and 240 separated by an insulator which comprises the novel high k nanolaminate layer 228 of embodiments of the present invention. The capacitor may be formed in a front-end-of the line (FEOL), or portions of the capacitor may be formed in the back-end-of the line (BEOL), for example. One or both of the capacitor plates 224 and 240 may be formed in a metallization layer of the semiconductor device 220, for example. Capacitors such as the one shown in FIG. 8 may be used in filters, in analog-to-digital converters, memory devices, control applications, and many other types of applications, for example.

FIG. 9 shows a cross-sectional view of a semiconductor device 320, wherein the novel high k dielectric material 328 of embodiments of the present invention is implemented in a transistor structure as a gate dielectric 328. Again, like numerals are used for the various elements that were used to describe the previous figures, and to avoid repetition, each reference number shown in FIG. 9 is not described again in detail herein. Note that in this embodiment, a SiₓN_{y} layer (not shown; see FIG. 6) may be disposed between the workpiece 321 and the nanolaminate layer 328, a nitrided layer 134 (also not shown) may be disposed over the nanolaminate layer 328, and a gettering layer 136 may also be included (not shown).

The transistor includes a gate dielectric comprising the novel nanolaminate layer 328 described herein and a gate electrode 340 formed over the nanolaminate layer 328. Source and drain regions 350 are formed proximate the gate electrode 340 in the workpiece, and a channel region is disposed between the source and drain regions 350. The transistor may be separated from adjacent devices by shallow trench isolation (STI) regions 352, and insulating spacers 354 may be formed on sidewalls of the gate electrode 340 and the gate dielectric 328, as shown.

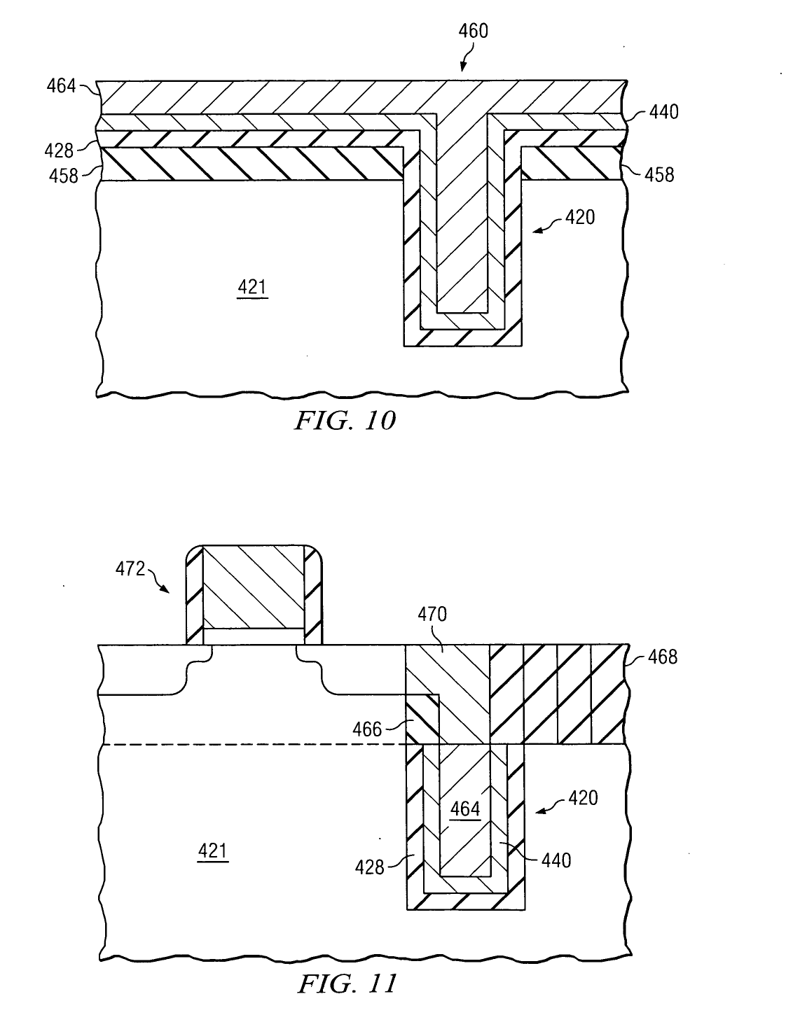

FIGS. 10 and 11 show cross-sectional view of a semiconductor device 420 at various stages of manufacturing, wherein the novel high k dielectric material 428 of embodiments of the present invention is implemented in a DRAM structure. To form a DRAM memory cell comprising a storage capacitor utilizing the nanolaminate material 428 of embodiments of the present invention, a sacrificial material 458 comprising an insulator such as a hard mask material is deposited over a workpiece 421, and deep trenches 460 are formed in the sacrificial material 458 and the workpiece 421. The novel nanolaminate layer 428 is formed over the patterned sacrificial material 458, and an electrode material 440 is formed over the nanolaminate layer 428, as shown. An additional electrode material 464 comprising polysilicon or other semiconductor or conductive material may be deposited over the electrode material 440 to fill the trenches 460, as shown in FIG. 10.

Next, excess amounts of materials 464, 440, and 428 are removed from over the top surface of the workpiece 421, e.g., using a chemical mechanical polish (CMP) process and/or etch process. The materials 464, 440, and 428 are also recessed below the top surface of the workpiece 421, for example. The sacrificial material 458 is also removed, as shown in FIG. 11.

An oxide collar 466 may be formed by thermal oxidation of exposed portions of the trench 460 sidewalls. The trench 460 may then be filled with a conductor such as polysilicon 470. Both the polysilicon 470 and the oxide collar 466 are then etched back to expose a sidewall portion of the workpiece 421 which will form an interface between an access transistor 472 and the capacitor formed in the deep trench 460 in the workpiece 421, for example.

After the collar 466 is etched back, a buried strap may be formed at 470 by deposition of a conductive material, such as doped polysilicon. Regions 464 and 470 comprising polysilicon are preferably doped with a dopant such as arsenic or phosphorus, for example. Alternatively, regions 464 and 470 may comprise a conductive material other than polysilicon (e.g., a metal).

The strap material 470 and the workpiece 421 may then be patterned and etched to form STI regions 468. The STI regions 468 may be filled with an insulator such as an oxide deposited by a high density plasma process (i.e., HDP oxide). The access transistor 472 may then be formed to create the structure shown in FIG. 11.

The workpiece 421 proximate the nanolaminate layer 428 lining the deep trench 460 comprises a first capacitor plate, the nanolaminate layer 428 comprises a capacitor dielectric, and materials 428 and 440 comprise a second capacitor plate of the deep trench storage capacitor of the DRAM memory cell. The access transistor 472 is used to read or write to the DRAM memory cell, e.g., by the electrical connection established by the strap 470 to a source or drain of the transistor near the top of the deep trench 460, for example.

Embodiments of the present invention may be implemented in other structures that require a dielectric material. For example, the novel nanolaminate layer 128, 228, 328, and 428 may be implemented in planar transistors, vertical transistors, planar capacitors, stacked capacitors, vertical capacitors, deep or shallow trench capacitors, and other devices. Embodiments of the present invention may be implemented in stacked capacitors where both plates reside above a substrate or workpiece, for example.

Advantages of embodiments of the present invention include providing novel methods and structures having a high dielectric constant or k value. The dielectric materials comprise a synthesis of a nanolaminate structure between an oxide and oxynitride or a silicate and a silicon oxynitride layer in order to optimize the composition of the stack, stabilize the high k phase of Hf or Zr oxide, and improve thickness uniformity. The nanolaminate structure provides a means to control the thickness of the individual oxide or silicate layer, thereby facilitating controlled nucleation and growth of the desired high k phase (tetragonal or cubic oxide). Further, the use of an optional titanium gettering layer enhances the dielectric constant of the nanolaminate stack while minimizing the effective oxide thickness (EOT).

Another benefit of embodiments of the present invention is providing the ability to fine tune the phases and composition of the film stack, e.g., of the nanolaminate layer 128. In addition, improved film uniformity is achieved due to the ease of HfSiON or ZrSiON film nucleation on an oxide or silicate starting layer (e.g. HfO₂ or HfSiO) of the nanolaminate layer 128, for example.

The entire dielectric stack including nanolaminate layer 128, and optionally also the nitride layer 126′ and nitrided layer 134, advantageously may have a dielectric constant of about 30 or greater in some embodiments, for example.

The use of the novel nanolaminate structure combined with an optional Ti-based gettering layer provides multiple benefits. The Hf:Si:O:N ratio in the stack 128 may be fine tuned to target the desired composition (such as a low silicon content, e.g., of 20% or less by atomic weight and a low nitrogen content, e.g., also about 20% or less by atomic weight) by varying the ratio of HfO₂/HfSiO/HfSiON ALD cycles, for example. The tetragonal phase of HfO₂ can be stabilized by optimizing the layer thickness.

The disadvantage of the lower band gap of nitrided HfSiON when used as a second layer 132 can be overcome by using a nanolaminate structure with HfO₂ or HfSiO as a first layer 130 in the nanolaminate structure 128. A Ti gettering layer 136 may be used to minimize the EOT for the stack, e.g., comprising 126′/128/134. A better uniformity of a material film layer may be achieved due to improved nucleation of the X—SiON (wherein X=Zr or Hf) layer on a starting HfO₂ or HfSiO layer, for example.

Although embodiments of the present invention and their advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A method of forming a material layer, the method comprising:
forming at least one first layer of a first material, the first material comprising an oxide or a silicate of Hf, Zr, or La; and
forming at least one second layer of a second material over the at least one first layer of the first material, the second material comprising a silicon oxynitride of Hf, Zr, or La.

2. The method according to claim 1, wherein the at least one first layer and the at least one second layer form a dielectric material.

3. The method according to claim 2, wherein the dielectric material comprises a plurality of alternating layers of the at least one first layer of the first material and the at least one second layer of the second material.

4. The method according to claim 3, further comprising varying a first number of the first layers of the first material and varying a second number of the second layers of the second material to adjust a dielectric constant of the dielectric material.

5. The method according to claim 1, wherein forming the at least one first material layer or the at least one second material layer comprise forming the at least one first material layer or the at least one second material layer by atomic layer deposition (ALD).

6. The method according to claim 1, wherein forming the at least one second layer of the second material comprises forming the same number, or a different number, of layers of the at least one first layer of the first material.

7. A method of fabricating a semiconductor device, the method comprising:
providing a workpiece;
forming at least one first layer of a first material over the workpiece, the first material comprising an oxide or a silicate of Hf, Zr, or La; and
forming at least one second layer of a second material over the at least one first layer of the first material, the second material comprising a silicon oxynitride of Hf, Zr, or La, wherein the at least one first layer of the first material and the at least one second layer of the second material comprise a dielectric material.

8. The method according to claim 7, wherein forming the at least one first layer of the first material and forming the at least one second layer of the second material comprise forming a nanolaminate layer.

9. The method according to claim 7, further comprising annealing the workpiece or exposing the workpiece to nitrogen, after forming a last layer of the at least one second layer of the second material.

10. The method according to claim 7, further comprising forming a gettering layer over a last layer of the at least one second layer of the second material.

11. The method according to claim 7, further comprising forming an electrode material over a last layer of the at least one second layer of the second material.

12. The method according to claim 7, further comprising, before forming the at least one first layer of a first material over the workpiece, forming a layer of oxide over the workpiece, and exposing the layer of oxide to nitrogen to form an oxynitride layer.

13. A semiconductor device, comprising:
a workpiece; and
a dielectric material disposed over the workpiece, the dielectric material comprising at least one first layer of a first material disposed over the workpiece, the first material comprising an oxide or a silicate of Hf, Zr, or La, the dielectric material further comprising at least one second layer of a second material disposed over the at least one first layer of the first material, the second material comprising a silicon oxynitride of Hf, Zr, or La.

14. The semiconductor device according to claim 13, wherein the first material comprises one or more monolayers of HfO₂, HfSiO, ZrO₂, or ZrSiO, and wherein the second material comprises one or more monolayers of HfSiON or ZrSiON.

15. The semiconductor device according to claim 13, wherein the dielectric material comprises a thickness of about 15 nm or less.

16. The semiconductor device according to claim 13, wherein the dielectric material further comprises a layer of nitride or a layer of oxynitride disposed over the workpiece beneath the at least one first layer of the first material.

17. The semiconductor device according to claim 13, wherein the dielectric material comprises a dielectric constant (k) of about 30 or greater.

18. The semiconductor device according to claim 13, wherein the dielectric material comprises a gate dielectric of a transistor, or wherein the dielectric material comprises a capacitor dielectric of a capacitor.

19. A semiconductor device, comprising:
a workpiece; and
a nanolaminate layer disposed over the workpiece, the nanolaminate layer comprising a dielectric material including alternating layers of at least one first layer of a first material and at least one second layer of a second material, the first material comprising an oxide or a silicate of Hf, Zr, or La, the second material comprising a silicon oxynitride of Hf, Zr, or La; and
an electrode disposed over the nanolaminate layer.

20. The semiconductor device according to claim 19, wherein the nanolaminate layer comprises a HfO₂—HfSiON nanolaminate material, a HfSiO—HfSiON nanolaminate material, a ZrO₂—ZrSiON nanolaminate material, a ZrSiO—ZrSiON nanolaminate material, a HfO₂—ZrSiON nanolaminate material, a ZrO₂—HfSiON nanolaminate material, a ZrSiO—HfSiON nanolaminate material, or a HfSiO—ZrSiON nanolaminate.

21. The semiconductor device according to claim 19, wherein the electrode comprises a gate electrode of a transistor, wherein the nanolaminate layer comprises a gate dielectric of the transistor, wherein the transistor further comprises a source region disposed in the workpiece, a drain region disposed in the workpiece, and a channel region disposed between the source region and the drain region in the workpiece.

22. The semiconductor device according to claim 19, wherein the nanolaminate layer comprises a capacitor dielectric, wherein the electrode comprises a first capacitor plate, wherein the nanolaminate layer comprises a first side proximate the electrode, further comprising a second capacitor plate proximate a second side of the nanolaminate layer, and wherein the first capacitor plate, the second capacitor plate, and the capacitor dielectric comprise a capacitor.

23. The semiconductor device according to claim 22, wherein the first capacitor plate and the second capacitor plate comprise a metal or a semiconductor.

24. The semiconductor device according to claim 19, wherein the electrode comprises TiN, TaN, RuO₂, TiSiN, or multiple layers or combinations thereof.

25. The semiconductor device according to claim 19, wherein the semiconductor device comprises a dynamic random access memory (DRAM) cell comprising a storage capacitor, the storage capacitor comprising a first capacitor plate comprising a portion of the workpiece of the semiconductor device, a capacitor dielectric comprising the nanolaminate layer, and a second capacitor plate adjacent to nanolaminate layer, and wherein the DRAM cell further comprises a transistor formed in the workpiece coupled to the first plate of the storage capacitor.
